(19) United States
(12) Patent Application Publication
(10) Pub. No.: US 2026/0332146 A1
(43) Pub. Date: Oct. 22, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventor: Masahiro ASANO, Ashigarakami Kanagawa (JP)

(21) Appl. No.: 19/354,107

(22) Filed: Oct. 9, 2025

(30) Foreign Application Priority Data
Apr. 22, 2025 (JP) 2025-070760

(51) Int. Cl. H03K 17/785

(52) U.S. Cl. CPC H03K 17/785

(57) ABSTRACT

According to one embodiment, a semiconductor device includes: a reception unit configured to generate power without a physical contact; a first transistor including a gate coupled to the reception unit and a first end coupled to a first node coupled to the reception unit; and a second transistor including a gate coupled to the first node and a first end coupled to a second end of the first transistor, the second transistor being a depletion-mode transistor, wherein the reception unit is configured to bring, using the power, the first transistor to an on state or an off state.

### CROSS-REFERENCE TO RELATED APPLICATION

This application is based upon and claims the benefit of priority from Japanese Patent Application No. 2025-070760, filed Apr.22, 2025, the entire contents of which are incorporated herein by reference.

### FIELD

Embodiments described herein relate generally to a semiconductor device.

### BACKGROUND

As a semiconductor device, a contactless relay used for transmitting alternating-current signals and direct-current signals is known. In such a semiconductor device, optical coupling, magnetic coupling, capacitive coupling, etc. are employed.

### BRIEF DESCRIPTION OF THE DRAWINGS

FIG. 1 is a circuit diagram for illustrating a circuit configuration of a semiconductor device according to an embodiment.

FIG. 2 is a circuit diagram for illustrating a circuit configuration of a semiconductor device according to a comparative example.

FIG. 3 is a circuit diagram for illustrating a circuit configuration of a semiconductor device according to a modification.

### DETAILED DESCRIPTION

In general, according to one embodiment, a semiconductor device includes: a reception unit configured to generate power without a physical contact; a first transistor including a gate coupled to the reception unit and a first end coupled to a first node coupled to the reception unit; and a second transistor including a gate coupled to the first node and a first end coupled to a second end of the first transistor, the second transistor being a depletion-mode transistor, wherein the reception unit is configured to bring, using the power, the first transistor to an on state or an off state.

The embodiments will be described with reference to the drawings. Note that, in the following description, components having the same function and configuration are denoted by the same reference numerals. The dimensions and radios in the drawings are not necessarily identical to real ones.

### 1. Embodiment

A semiconductor device according to an embodiment will be described.

The semiconductor device according to the embodiment is, for example, a photo-relay device for transmitting alternating-current signals and direct-current signals. The semiconductor device according to the embodiment is, for example, a package of an electronic component. In the description that follows, alternating-current signals and direct-current signals will be simply referred to as “signals”.

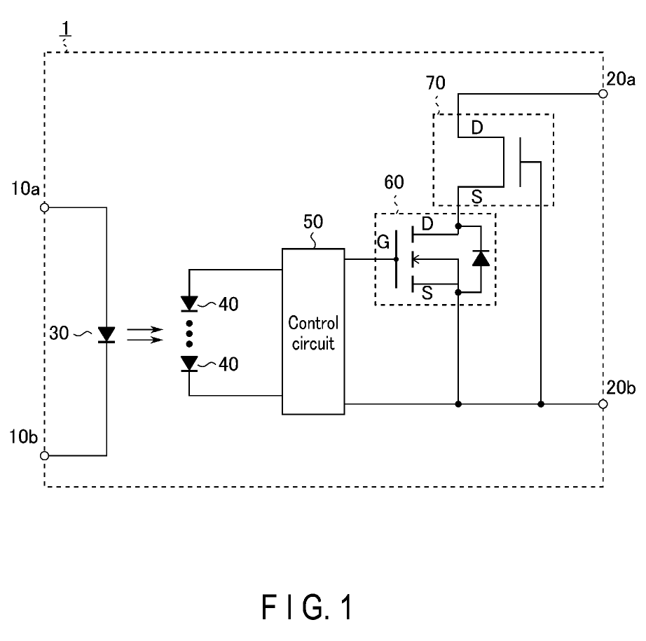

An example of a circuit configuration of the semiconductor device according to the embodiment will be described with reference to FIG. 1. FIG. 1 is a circuit diagram for illustrating a circuit configuration of a semiconductor device according to an embodiment.

A semiconductor device 1 includes terminals 10a, 10b, 20a, and 20b. The terminals 10a and 10b are supplied with power for driving the semiconductor device 1. During driving of the semiconductor device 1, the semiconductor device 1 can transmit signals via the terminals 20a and 20b.

The semiconductor device 1 includes a light emitter 30, a plurality of photoelectric elements 40, a control circuit 50, a metal-oxide-semiconductor field-effect transistor (MOSFET) 60, and a transistor 70. The light emitter 30 is, for example, a light-emitting diode (LED). The photoelectric elements 40 are, for example, photodiodes or phototransistors. Hereinafter, a case will be described where the photoelectric elements 40 are photodiodes. The photoelectric elements 40 are also referred to as “photodiodes 40”. The MOSFET 60 is an N-channel enhancement-mode MOSFET. The transistor 70 is a depletion-mode (normally on) transistor. The transistor 70 is, for example, an N-channel transistor.

The light emitter 30 is coupled between the terminals 10a and 10b. More specifically, an anode electrode of the light emitter 30 is coupled to, for example, the terminal 10a. A cathode electrode of the light emitter 30 is coupled to, for example, the terminal 10b. The light emitter 30 is driven by power supplied to the terminals 10a and 10b. Thereby, the light emitter 30 is turned to an on state (turned-on state) or an off state (turned-off state).

The plurality of photodiodes 40 include, for example, a few to a few dozen photodiodes 40. Both ends of the plurality of photodiodes 40 coupled in series are coupled to the control circuit 50. The control circuit 50 turns the MOSFET 60 to an on state using photovoltaic power generated by the plurality of photodiodes 40. Note that a configuration including the plurality of photodiodes 40 and the control circuit 50 will also be referred to as a “light receiver” or a “reception unit”.

A source of the MOSFET 60 is coupled to a cathode electrode of the control circuit 50 and to the terminal 20b. A gate of the MOSFET 60 is coupled to an anode electrode of the control circuit 50.

Note that the MOSFET 60 is an enhancement-mode or depletion-mode MOSFET. In the semiconductor device 1 applied to an arbeit (normally open) contact, the MOSFET 60 is an enhancement-mode MOSFET. In the semiconductor device 1 applied to a break (normally closed) contact, the MOSFET 60 is a depletion-mode MOSFET.

The transistor 70 is, for example, a junction field-effect transistor (JFET) which uses a silicon carbide (SiC), or a D-mode high-electron-mobility transistor (HEMT) which uses a gallium nitride (GaN). The transistor 70 has a high withstand voltage and is capable of supplying a large current. The transistor 70 has, for example, a higher withstand voltage than the MOSFET 60.

A source of the transistor 70 is coupled to a drain of the MOSFET 60. A drain of the transistor 70 is coupled to the terminal 20a. A gate of the transistor 70 is coupled to the terminal 20b. Thereby, the transistor 70 is brought to an on state or an off state in accordance with a drain-to-source voltage of the MOSFET 60 equivalent to a reverse-biased gate-to-source voltage of the transistor 70. With the above-described configuration, the transistor 70 is cascode-coupled to the MOSFET 60.

In the circuit configuration of the semiconductor device 1, if the light emitter 30 is brought to an on state from an off state, light of the light emitter 30 is irradiated onto the photodiodes 40. The light receiver brings the enhancement-mode MOSFET 60 to an on state from an off state, using photovoltaic power generated by the light of the light emitter 30. With the MOSFET 60 brought to the on state from the off state, the transistor 70 is brought to an on state from an off state in accordance with a decrease in the drain-to-source voltage of the MOSFET 60. Thereby, the terminals 20a and 20b are electrically coupled.

In addition, with the light emitter 30 brought to the off state from the on state, irradiation of light from the light emitter 30 is stopped. Thereby, the enhancement-mode MOSFET 60 is brought to the off state from the on state. With the MOSFET 60 brought to the off state from the on state, the transistor 70 is also brought to the off state from the on state in accordance with an increase in the drain-to-source voltage of the MOSFET 60. In the above-described manner, the semiconductor device 1 electrically insulates positive voltage signals applied in a direction from the terminal 20a to the terminal 20b.

Note that the light emitter 30, the photoelectric elements 40, the control circuit 50, the MOSFET 60, and the transistor 70 are provided on, for example, a substrate (not illustrated). Such elements provided on the substrate are sealed by a sealing material. That is, the semiconductor device 1 is packaged.

There is a demand for a semiconductor device used as a contactless relay to have a high withstand voltage and to be able to supply a large current. According to the embodiment, it is possible to improve withstand voltage characteristics and current characteristics of the semiconductor device 1. Hereinafter, improvement in withstand voltage characteristics and current characteristics of the semiconductor device 1 according to the embodiment will be described.

The semiconductor device 1 according to the embodiment includes a light receiver, a MOSFET 60, and a transistor 70. The MOSFET 60 is an N-channel MOSFET. The transistor 70 is a depletion-mode transistor. The transistor 70 is, for example, an N-channel transistor. A gate of the MOSFET 60 is coupled to an anode electrode of a control circuit 50 of the light receiver. A source of the MOSFET 60 is coupled to a terminal 20b. A gate of the transistor 70 is coupled to the terminal 20b. A source of the transistor 70 is coupled to a drain of the MOSFET 60. The light receiver is configured to bring the MOSFET 60 to an on state or an off state using photovoltaic power. With the above-described configuration, it is possible to improve the withstand voltage characteristics and current characteristics of the semiconductor device 1.

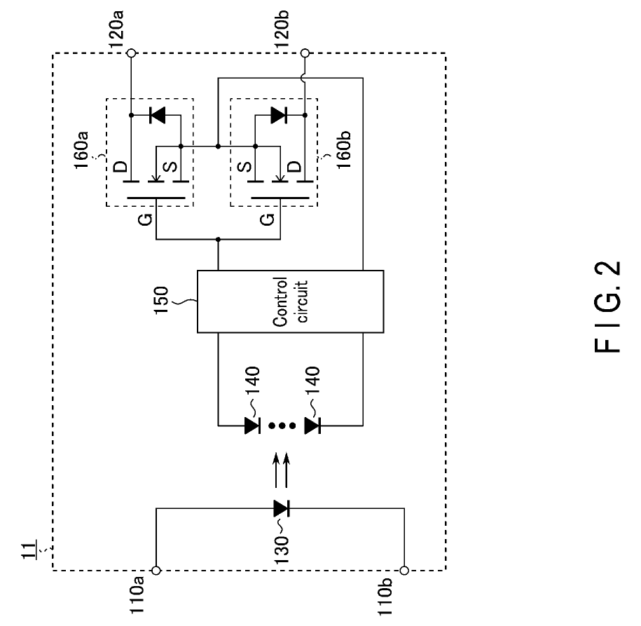

The above-described feature will be further described using a semiconductor device 11 according to a comparative example shown in FIG. 2. FIG. 2 is a circuit diagram for illustrating an example of a circuit configuration of a semiconductor device according to a comparative example. The semiconductor device 11 according to the comparative example includes terminals 110a, 110b, 120a, and 120b, a light emitter 130, a plurality of photodiodes 140 coupled in series, a control circuit 150, and MOSFETs 160a and 160b. Note that a configuration including the plurality of photodiodes 140 and the control circuit 150 will also be referred to as a “light receiver”. The MOSFETs 160a and 160b are, for example, N-channel MOSFETs. A gate of the MOSFET 160a and a gate of the MOSFET 160b are controlled in common by the control circuit 150. A source of the MOSFET 160a and a source of the MOSFET 160b are coupled to each other. A drain of the MOSFET 160a is coupled to the terminal 120a. A drain of the MOSFET 160b is coupled to the terminal 120b. The control circuit 150 controls a potential of a gate of the MOSFET 160a and a potential of a gate of the MOSFET 160b using photovoltaic power from the photodiodes 140. Thereby, the control circuit 150 controls transmission of signals between the terminals 120a and 120b.

In order to allow the semiconductor device 11 to have a high withstand voltage and to be able to supply a large current in the comparative example, the MOSFETs 160a and 160b, for example, are configured as transistors having a high withstand voltage and capable of providing a large current. In this case, since the MOSFETs 160a and 160b are configured to have a high withstand voltage and to be able to supply a large current, the driving voltages of the MOSFETs 160a and 160b inevitably increase. Thus, to prevent a shortage of driving voltage, an increase in the size of the light receiver for the purpose of increasing the output of the light receiver and an increase in cost of the light receiver involved therewith, for example, may become problematic.

In addition, if the MOSFETs 160a and 160b are configured to have a high withstand voltage and to be able to supply a large current, the safe operating area may be exceeded at the turn-on and turn-off of the MOSFETs. This will be discussed in further detail below.

The withstand voltage characteristics and the current characteristics of the MOSFETs 160a and 160b are in a trade-off relationship with the gate input capacity, the gate charge, and the safe operating area of the MOSFETs. That is, if the MOSFETs are configured to have a high withstand voltage and to be able to supply a large current, the gate input capacity and the gate charge of the MOSFETs also inevitably increase.

The gate charging period (turn-on period) and the gate discharging period (turn-off period) of a MOSFET are based on a relationship formula (Q=It) of a current I, a time t during which the current I has flown, and a charge Q. In the semiconductor device 11, there is a restriction to the gate discharging/charging current, as well as the driving voltage, of the light receiver, due to size and cost issues.

It is possible, for example, to increase the current flowing through the terminals 110a and 110b, to increase the light output of the light emitter 130, and to increase the driving voltage and the gate charging current of the light receiver. In this case, however, the power consumption of the light emitter 130 inevitably increases. Thereby, the light output of the light emitter 130 tends to decrease. That is, the light emitter 130 becomes easily deteriorated. Accordingly, the increase in the light output of the light emitter 130 results in a decrease in the lifespan and reliability of the semiconductor device 11.

Moreover, if, for example, the control circuit 150 is configured only with a resistor for cost reduction, it is necessary to increase the resistance value of the resistor to provide a sufficiently high driving voltage. In this case, however, the gate discharging current inevitably decreases.

The gate charging period (turn-on period) and the gate discharging period (turn-off period) of a MOSFET increase as the gate charging current or the gate discharging current decreases, or the gate charge increases (the switching speed decreases). The turn-on period and the turn-off period are associated with derating conditions of a safe operating area of the MOSFET, and the safe operating area of the MOSFET becomes narrower as the turn-on period and the turn-off period increase. Accordingly, if the MOSFETs 160a and 160b are configured to have a high withstand voltage and to be able to supply a large current, the switching control of the semiconductor device 11 may be performed beyond the safe operating area of the MOSFETs 160a and 160b.

As can be seen from the above-described circumstances, it is difficult, with the comparative example, to configure the MOSFETs 160a and 160b to have a high withstand voltage and to be able to supply a large current.

According to the embodiment, the MOSFET 60 and the transistor 70 are coupled between the terminals 20a and 20b. Of the gate of the MOSFET 60 and the gate of the transistor 70, the light receiver supplies power only to the gate of the MOSFET 60. Thereby, the MOSFET 60 is directly driven by a current supplied from the light receiver. On the other hand, the transistor 70 is driven in accordance with a drain-to-source voltage of the MOSFET 60 equivalent to a reverse-biased gate-to-source voltage of the transistor 70. That is, the transistor 70 is indirectly driven by a current supplied from the light receiver. With the above-described configuration, the semiconductor device 1 is capable of transmitting a signal according to the load and the power level coupled to the terminals 20a and 20b.

In addition, in the embodiment, the source of the MOSFET 60 and the gate of the depletion-mode transistor 70 are directly coupled. Thereby, the MOSFET 60 is brought to an on state from an off state, and the transistor 70 is brought to an on state from an off state in accordance with a decrease in the drain-to-source voltage of the MOSFET 60. With the above-described configuration, in the case of allowing the semiconductor device 1 to have a high withstand voltage and to be able to supply a large current, it is possible in the embodiment to configure the depletion-mode transistor 70 to have a high withstand voltage while suppressing the MOSFET 60 from increasing in withstand voltage. It is thereby possible in the embodiment to suppress the driving voltage, the gate input capacity, and the gate charge, as compared to, for example, the MOSFETs 160a and 160b configured to have a high withstand voltage and to be able to supply a large current according to the comparative example. That is, according to the embodiment, in the case of allowing the semiconductor device to have a high withstand voltage and to provide a large current, it is possible to suppress the increase in the size and cost of the light receiver, the increase in the power consumption amount of the light emitter 30, the decrease in the lifespan and reliability of the semiconductor device 11, and the operation of the semiconductor device beyond the safe operating areas of the MOSFET 60 and the transistor 70.

### 2. Modification

Next, a semiconductor device according to a modification will be described. Hereinafter, descriptions of configurations similar to those of the embodiment will be omitted, and configurations different from those of the embodiment will be mainly described.

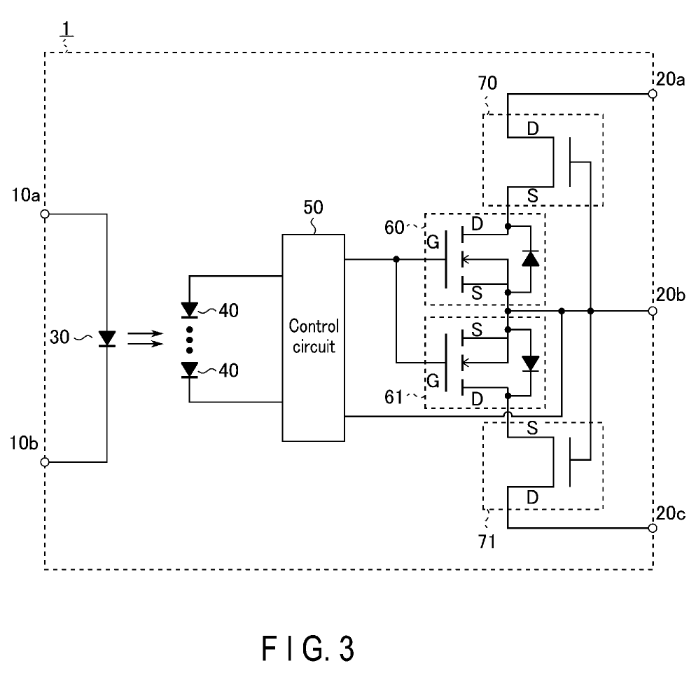

A semiconductor device according to a modification will be described with reference to FIG. 3. FIG. 3 is a circuit diagram for illustrating a circuit configuration of a semiconductor device according to a modification.

A semiconductor device 1 according to the modification further includes a terminal 20c, a MOSFET 61, and a transistor 71.

The MOSFET 61 is, for example, a transistor similar to the MOSFET 60. That is, the MOSFET 61 is, for example, an enhancement-mode or depletion-mode N-channel MOSFET.

A source of the MOSFET 61 is coupled to a cathode electrode of a control circuit 50 and to a terminal 20b, similarly to a source of the MOSFET 60. A gate of the MOSFET 61 is coupled to an anode electrode of the control circuit 50, similarly to a gate of the MOSFET 60. The MOSFET 61 is brought to an on state or an off state by the control circuit 50, similarly to the MOSFET 60.

The transistor 71 is a depletion-mode transistor which has a high withstand voltage and is capable of supplying a large current, similarly to the transistor 70. The transistor 71 is, for example, an N-channel transistor, similarly to the transistor 70. The transistor 71 is, for example, a transistor similar to the transistor 70. The transistor 71 is, for example, a transistor having a higher withstand voltage than the MOSFET 61.

A source of the transistor 71 is coupled to a drain of the MOSFET 61. A drain of the transistor 71 is coupled to the terminal 20c. A gate of the transistor 71 is coupled to the terminal 20b. Thereby, the transistor 71 is brought to an on state or an off state in accordance with a drain-to-source voltage of the MOSFET 61 equivalent to a reverse-biased gate-to-source voltage of the transistor 71. With the above-described configuration, the transistor 71 is cascode-coupled to the MOSFET 61.

In addition, with the above-described configuration, the MOSFETs 60 and 61 are back-to-back coupled. That is, the pair of the MOSFET 60 and the transistor 70 and the pair of the MOSFET 61 and the transistor 71 are back-to-back coupled.

In the above-described circuit configuration of the semiconductor device 1, if the light receiver is irradiated with light from the light emitter 30, the light receiver brings the enhancement-mode MOSFETs 60 and 61 to an on state from an off state. Thereby, the transistors 70 and 71 are brought to an on state from an off state in accordance with a decrease in drain-to-source voltages of the MOSFETs 60 and 61. Thereby, the terminals 20a and 20c are electrically coupled.

Moreover, with stopping the irradiation of light from the light emitter 30, the MOSFETs 60 and 61 are brought to the off state from the on state. Furthermore, the transistors 70 and 71 are also brought to the off state from the on state in accordance with an increase in the drain-to-source voltages of the MOSFETs 60 and 61. In the above-described manner, the semiconductor device 1 provides electrical insulation between the terminals 20a and 20c.

In addition, according to the modification, it is possible to control positive-voltage and negative-voltage signals between the terminals 20a and 20c.

### 3. Others

In the above-described embodiment and its modification, a case has been described where the semiconductor device 1 uses optical coupling by means of a light emitter and a light receiver; however, the configuration is not limited thereto. The semiconductor device may use, for example, power based on magnetic coupling or capacitive coupling, instead of photovoltaic power based on optical coupling. In this case, the semiconductor device 1 includes, for example, an input unit and a reception unit, instead of the light emitter and the light receiver. The input unit and the reception unit generate power by means of magnetic coupling or capacitive coupling. The reception unit drives the MOSFETs 60 and 61 using thus-generated power.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a reception unit configured to generate power without a physical contact;
a first transistor including a gate coupled to the reception unit and a first end coupled to a first node coupled to the reception unit; and
a second transistor including a gate coupled to the first node and a first end coupled to a second end of the first transistor, the second transistor being a depletion-mode transistor, wherein
the reception unit is configured to bring, using the power, the first transistor to an on state or an off state.

2. The semiconductor device according to claim 1, further comprising:
a light emitter, wherein
the reception unit includes a photoelectric element, and uses, as the power, photovoltaic power generated by the photoelectric element through emission of light by the light emitter.

3. The semiconductor device according to claim 1, wherein
the second transistor has a higher withstand voltage than the first transistor.

4. The semiconductor device according to claim 1, wherein
the second transistor is a junction field-effect transistor or a high-electron-mobility transistor.

5. The semiconductor device according to claim 1, wherein
the first transistor is an enhancement-mode or depletion-mode transistor.

6. The semiconductor device according to claim 1, further comprising:
a third transistor including a gate coupled to the reception unit in common with the gate of the first transistor and a first end coupled to the first node; and
a fourth transistor including a gate coupled to the first node and a first end coupled to a second end of the third transistor, the fourth transistor being a depletion-mode transistor, wherein
the reception unit is configured to bring, using the power, the third transistor to an on state or an off state, in addition to the first transistor.

7. The semiconductor device according to claim 6, wherein
the first transistor and the third transistor are back-to-back coupled.

8. The semiconductor device according to claim 1, wherein
the reception unit is configured to generate the power by using magnetic coupling or capacitive coupling.

9. The semiconductor device according to claim 1, wherein
the reception unit, the first transistor, and the second transistor are sealed by a sealing material.

10. The semiconductor device according to claim 6, wherein
the fourth transistor has a higher withstand voltage than the third transistor.

11. The semiconductor device according to claim 6, wherein
the fourth transistor is a junction field-effect transistor or a high-electron-mobility transistor.

12. The semiconductor device according to claim 6, wherein
the third transistor is an enhancement-mode or depletion-mode transistor.
